(19) United States
(12) Patent Application Publication
(10) Pub. No.: US 2018/0144982 A1
(43) Pub. Date: May 24, 2018

(54) SEMICONDUCTOR DEVICES AND METHODS FOR MANUFACTURING SEMICONDUCTOR DEVICES

(71) Applicant: Infineon Technologies AG, Neubiberg (DE)

(72) Inventors: Ingo Muri, Villach (AT); Oliver Hellmund, Neubiberg (DE); Iris Moder, Villach (AT); Hans-Joachim Schulze, Taufkirchen (DE)

(21) Appl. No.: 15/809,280

(22) Filed: Nov. 10, 2017

(30) Foreign Application Priority Data
Nov. 23, 2016 (DE) 102016122637.8

(51) Int. Cl. H01L 21/78; H01L 21/265; H01L 21/3205; H01L 23/14

(52) U.S. Cl. CPC H01L 21/78; H01L 23/14; H01L 21/32051; H01L 21/265

(57) ABSTRACT

A method is disclosed for use in manufacturing semiconductor dice. The method comprises providing a wafer substrate that comprises dicing areas, providing a first etch stop material outside the dicing areas, and etching the wafer substrate down to the first etch stop material. A semiconductor device chip is also disclosed. The semiconductor device chip comprises a device layer comprising a semiconductor device and a metal support layer supporting the device layer. The metal support layer provides a metal side wall protection of the device layer.

### CROSS-REFERENCE TO RELATED APPLICATIONS

This application claims priority to German Patent Application No. 102016122637.8, filed on Nov. 23, 2016, which application is hereby incorporated herein by reference.

### TECHNICAL FIELD

The present invention relates generally to semiconductor devices, and, in particular embodiments, to methods for manufacturing semiconductor devices.

### BACKGROUND

Semiconductor devices are manufactured using semiconductor wafers. A semiconductor wafer can be provided with a plurality of active portions that each comprise a semiconductor device.

In a process called dicing, the wafer can be cut into dice or dies. The dice respectively comprise one of the active portions that, before dicing, were provided on the wafer. Dicing can be performed by sawing. Sawing can cause the semiconductor die to crack. A crack can compromise functionality of the semiconductor device.

Etching can be performed to sever the wafer and thus the dice from one another. Compared with sawing, etching takes a lot of time for an etchant to work itself through the wafer substrate.

### SUMMARY

In an aspect, a method comprises providing a wafer substrate that comprises dicing areas. The method further comprises depositing a first etch stop material outside the dicing areas. At least one effect can be that a first etch stop layer can be formed. Some embodiments further comprise etching the wafer substrate. At least one effect can be that etchant can form trenches between areas that are covered by etch stop material deposited to form the first etch stop layer.

### BRIEF DESCRIPTION OF THE DRAWINGS

The claimed subject matter is described below with reference to the drawings. As used herein, like terms refer to like elements throughout the description. The detailed description references the accompanying figures. The same numbers can be used throughout the drawings to reference like features and components. Further, in different drawings like features or corresponding features can be indicated by reference numerals that have the last two digits in common. It should be noted that views of exemplary embodiments are merely to illustrate selected features of the embodiment. In particular, cross-sectional views are not drawn to scale and dimensional relationships of the illustrated structures can differ from those of the illustrations.

FIGS. 1A and 1B illustrate a flow chart of a method in an exemplary embodiment according to concepts underlying the present disclosure.

FIGS. 2A to 2M illustrate a cross-sectional view of a wafer portion according to some embodiments at selected steps in a manufacturing process according to the method of the flow chart illustrated in FIGS. 1A and 1B.

FIG. 3 illustrates a cross-sectional side view of a semiconductor die that can result from a manufacturing process using steps of an exemplary method according to some implementations.

FIGS. 4A and 4B illustrate a cross-sectional view of a wafer portion according to some embodiments at selected steps in a manufacturing process according to the method of the flow chart illustrated in FIGS. 1A and 1B.

### DETAILED DESCRIPTION OF ILLUSTRATIVE EMBODIMENTS

For purposes of explanation, numerous specific details are set forth in order to provide a thorough understanding of the claimed subject matter. It may be evident, however, that the claimed subject matter may be practised without these specific details.

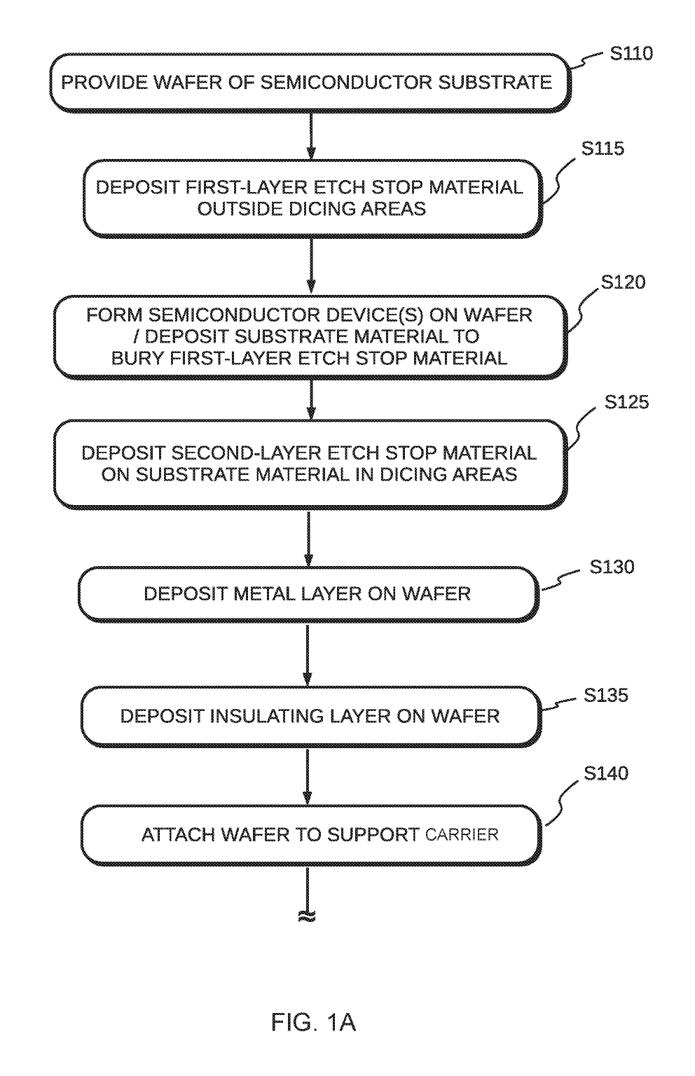

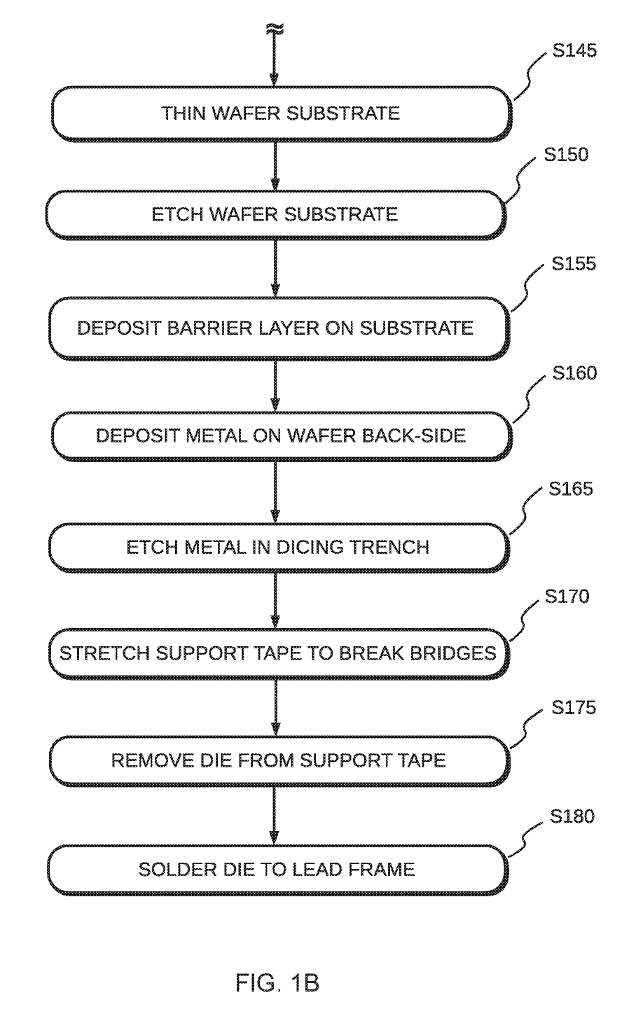

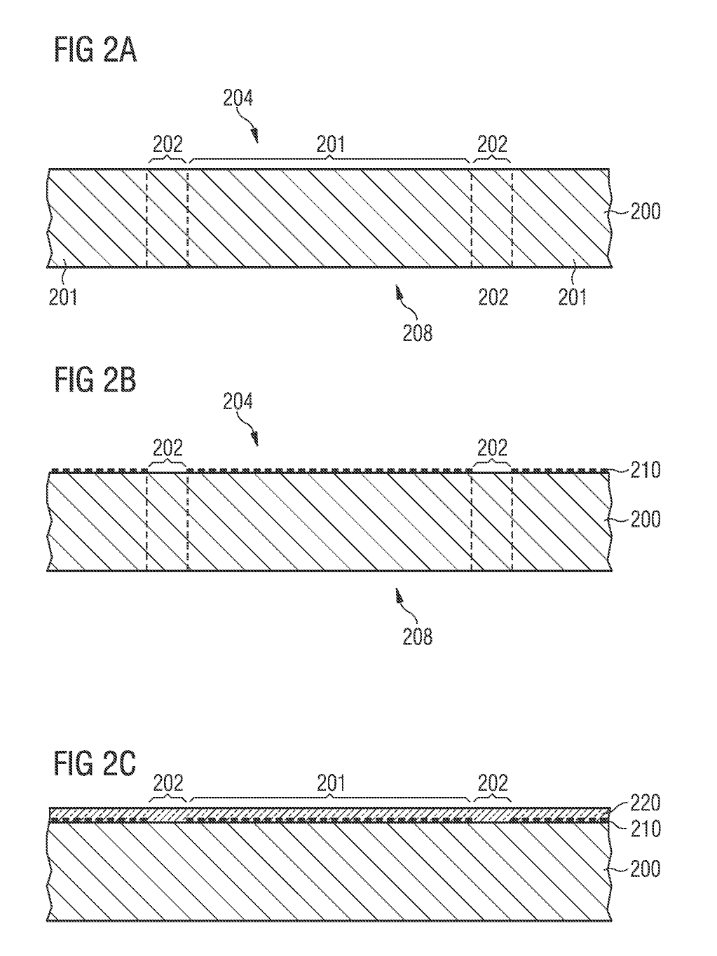

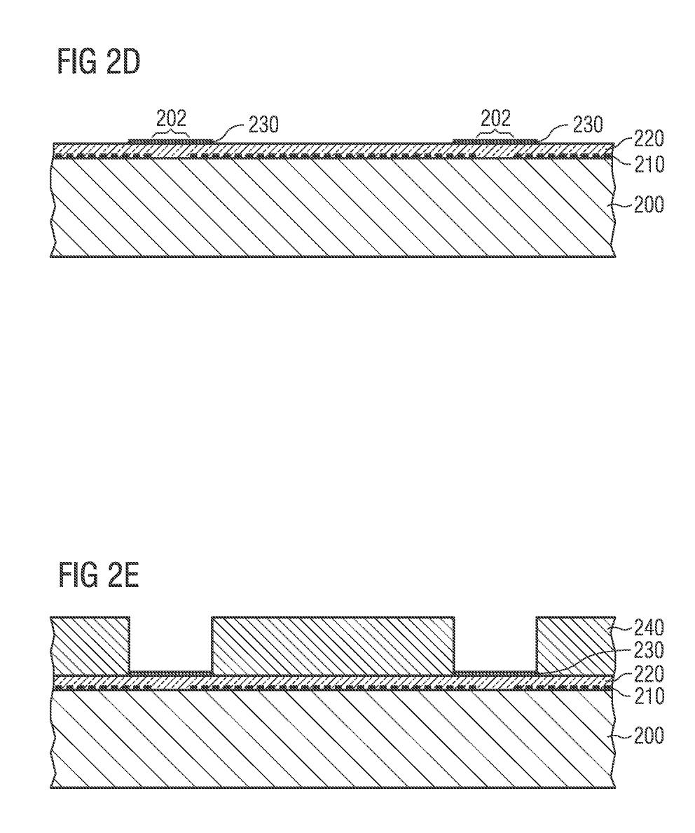

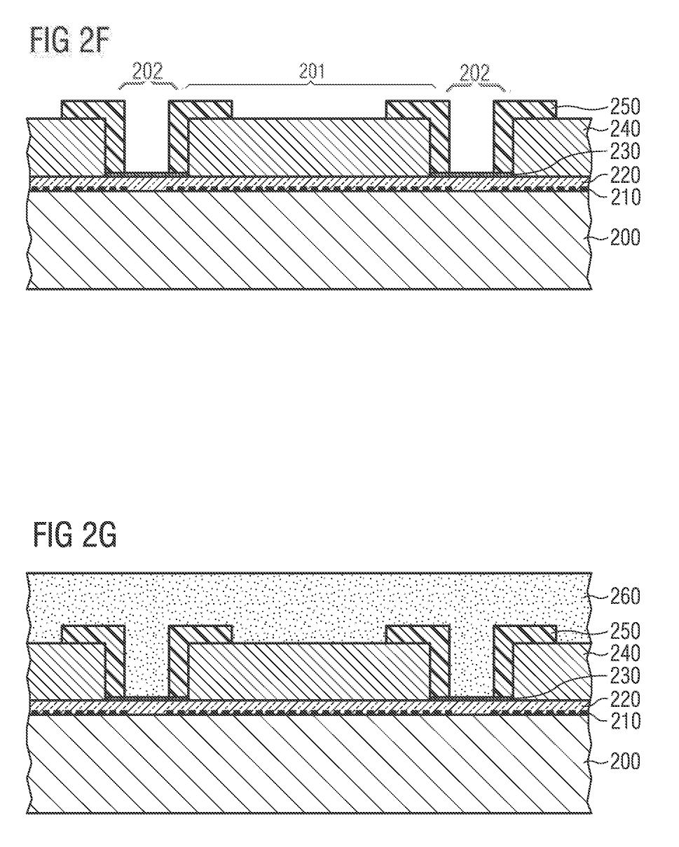

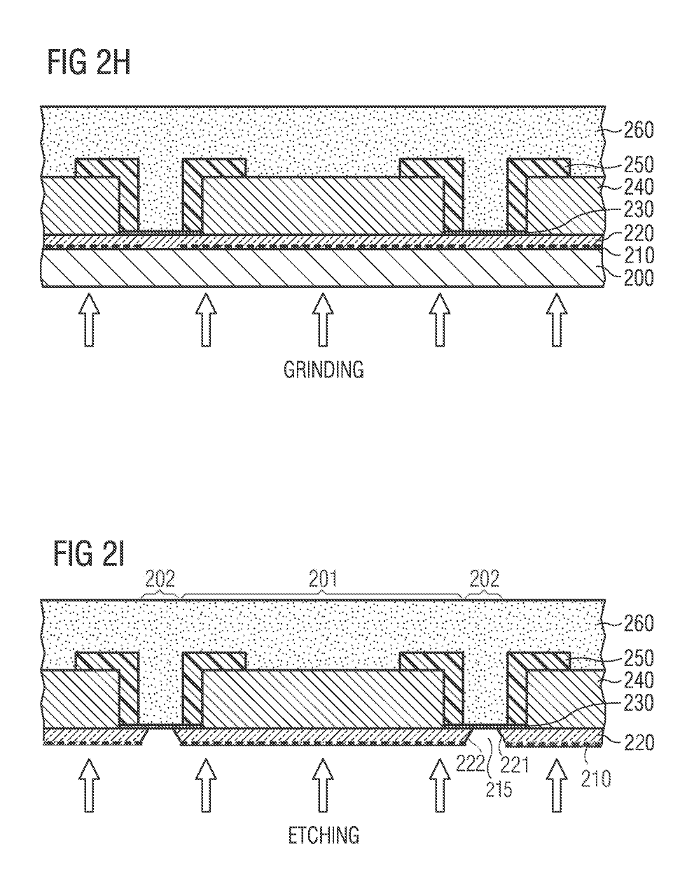

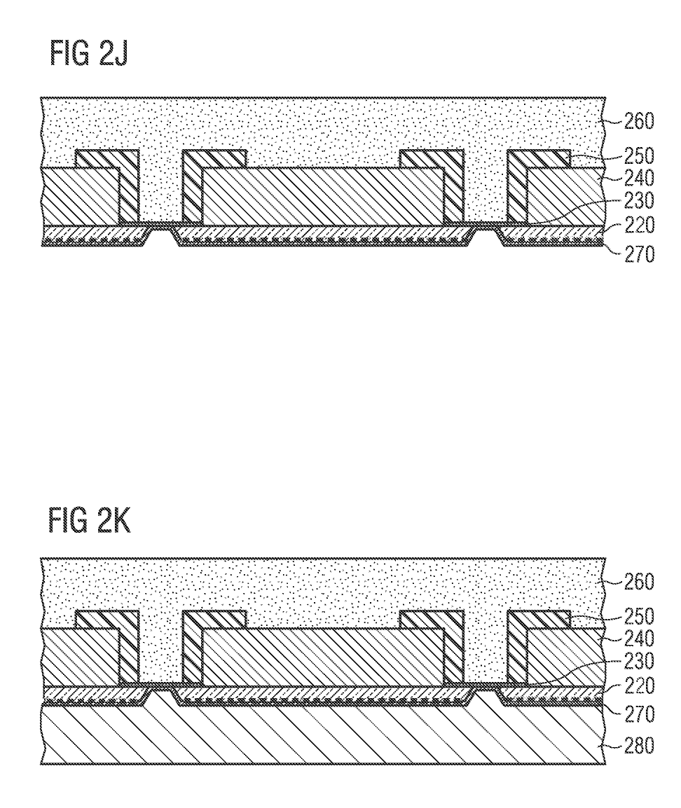

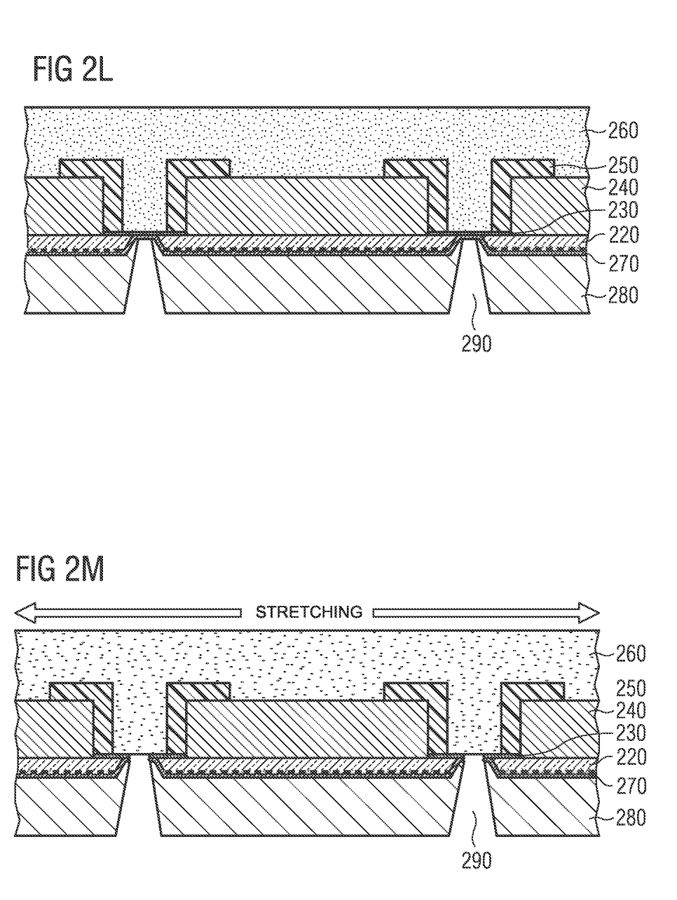

FIGS. 1A and 1B illustrate a flow chart of a method in an exemplary embodiment according to the concepts underlying the present disclosure. In particular, the exemplary method can be used in manufacturing semiconductor dice. Below, steps of the process depicted in FIGS. 1A and 1B will be described with reference to FIGS. 2A to 2M that illustrate a cross-sectional view of a wafer portion according to some embodiments at selected steps in a manufacturing process according to the method illustrated in FIGS. 1A and 1B. The sequence of steps shown should not be understood to be limiting. Rather, the person skilled in the art understands that some of the steps can be performed simultaneously or in another order than shown or discussed herein.

At S110, a wafer 200 comprising a substrate material is provided as illustrated in FIG. 2A. In some embodiments, the substrate material is a semiconductor. For example, the wafer is a silicon wafer or a silicon carbide wafer. In accordance with the purpose of the concepts underlying the present disclosure, in particular the purpose of processing the wafer 200 to manufacture semiconductor devices, the wafer can have a plurality of first portions that are destined to support one or more semiconductor devices and second portions that are destined to support bridges or other structural couplings between semiconductor devices. It should be understood that the bridges or other structural couplings between semiconductor devices can be configured to be lost in the process of severing the first portions from one another. In the figures, a broken line is used to indicate a border between the first portion and the second portion. However, it should be understood that, as long as the wafer substrate is not structured, the broken lines do not represent any structural inhomogeneity but merely indicate a design of how the wafer substrate is used in the manufacturing process that follows.

While the first portions, as will be seen below, in the course of the manufacturing process can provide so-called active areas 201 of the wafer, the second portions can provide dicing areas 202 of the wafer. Thus, the exemplary method comprises providing the wafer 200 having dicing areas 202. The wafer substrate 200 is to support semiconductor devices that are formed each in an active area 201 outside the dicing areas 202. In some embodiments, the wafer substrate 200 is homogenous. In particular, either face or side of the wafer substrate 200 can be structurally the same. Nevertheless, below reference will be made to a front face 204 of the wafer and a back face 208 of the wafer substrate 200. As front face 204 of the wafer substrate 200 will be denoted the face upon which the semiconductor device is formed. In contrast, as back face 208 of the wafer 200 will be denoted the face of the wafer that is opposite to the front face 204. Below, a plane with or parallel to the front face 204 of the wafer substrate 200 will be referred to as a support plane of the semiconductor device.

At S115, a first etch stop layer 210 comprising a first-layer etch stop material is provided, as illustrated, for example in FIG. 2B, on the front face 204 of the wafer 200, outside dicing areas 202. In some embodiments, the first-layer etch stop material is selected from a group consisting of oxide, graphite, nitride, carbide, and combinations thereof. For example, the first-layer etch stop material is deposited by way of chemical vapor deposition or by cathodic arc plasma deposition. In particular, the first etch stop layer 210 can be patterned. For example, the pattern of the first etch stop layer 210 can be such that the first-layer etch stop material covers active areas 201, but does not cover dicing areas 202. The pattern can, for example, be stripe-like or rectangular-like or circle-like. Thus, the first etch stop layer 210 can provide a protective barrier for the semiconductor device while leaving exposed those portions of the wafer substrate that are to be lost, in particular, when severing dice from the wafer 200.

At S120, after depositing the first-layer etch stop material, in some implementations, a device layer 220 of semiconductor material, for example, wafer material, in particular, substrate material, is deposited on the first etch stop layer 210 as indicated in the exemplary embodiment illustrated in FIG. 2C. One or more processing steps can be performed in order to form semiconductor devices (not specifically shown) in the device layer 220.

For example, semiconductor devices can be integrated circuit (IC) devices, power transistors (like for example IGBTs, power MOSFETs or power diodes) or micro-electrical mechanical system (MEMS) devices. In particular, such devices can be formed above the first portions, i.e., in the active areas 201 of the wafer substrate 200. In some embodiments, further devices (not shown) are formed above the second portions 202 of the wafer substrate 200. For example, test circuitry for use in wafer testing and to be lost when severing dice from the wafer can be formed above the second portions 202.

As will be described below, the device layer 220 of semiconductor material is to form an active semiconductor base of the die. The device layer 220, for example, can comprise the same type of material as the material of the wafer substrate 201, for example, silicon or silicon carbide. In some implementations, the device layer 220 is formed by epitaxial deposition of the semiconductor material on the first etch stop layer 210, for example by chemical vapour deposition. At least one effect can be that, as shown, for example, in FIG. 2C, the first etch stop layer 210 becomes buried beneath the substrate material of the device layer 220.

In some embodiments, a thickness of the device layer 220 is selected to provide a blocking capability designed to inhibit flow of current if a voltage is applied that is above a predetermined breakdown voltage. At least one effect can be that the thickness of the device layer 220 is adapted to provide a blocking capability above the predetermined breakdown voltage between an active circuit portion formed atop the wafer and the first etch stop layer 210 or, in some embodiments, between the active circuit portion and a field stop region which can be implemented in a later process step closely above (e.g., 1 to 10 micrometer) the first etch stop layer 210. In some embodiments the thickness of the active material layer is less than 10 micrometer. In some implementations, the exemplary method is accordingly used to manufacture low-voltage power transistors that have a low breakdown voltage.

At S125, after having buried the first etch stop layer 210, a second etch stop layer 230, is deposited above the device layer 220, e.g., on the substrate material that was deposited to bury the first etch stop layer 210. The second etch stop material layer 230 can be patterned. In particular, the second etch stop material layer 230 is formed so as to provide the second etch stop layer 230 above the dicing areas 202. It should be understood that the skilled person can also contemplate an implementation where the second etch stop layer 230 is provided to cover more of the wafer than merely the dicing areas 202. In some embodiments the second etch stop material is selected from a group consisting of oxide, graphite, nitride, carbide, and combinations thereof.

At S130, one or more processing steps can be performed in order to form a top metal layer 240 above the wafer substrate 200 as indicated, for example, in FIG. 2E. For example, the top metal layer 240 comprises copper. In some embodiments, the top metal layer 240 is provided as a copper layer. In some embodiments, the top metal layer is structured (not shown). For example, the top metal layer can comprise terminals, for example, a gate terminal and/or a source terminal. In some embodiments, for example some silicon-based insulated gate bipolar transistors (IGBTs) or power-MOSFETs with blocking voltages exceeding 400 V (e.g., 600 V IGBTs, 1200 V IGBTs, 1700 V IGBTs), a thickness of the device layer 220 together with the top metal layer 240 can exceed 50 micrometer or even 100 micrometer or even 150 micrometer.

At S135, in some implementations, an insulating layer 250 is deposited on the wafer as shown in FIG. 2F. For example, an oxide such as silicon dioxide can be deposited to form the insulating layer 250. The insulating layer 250 can be patterned and formed so as to provide an insulation of edge portions of the semiconductor devices manufactured in active areas of the wafer. In some embodiments, therefore, side walls of the active areas 201 facing the dicing areas 202 become covered by the insulating layer 250.

At S140, using an adhesive, the wafer is attached to a carrier plate as an adhesive carrier 260 as is shown, for example, in FIG. 2G. At least one effect can be that the adhesive carrier 260 supports the wafer. In particular, the adhesive carrier 260 can hold together portions of the wafer that, in the course of processing the wafer, become weakly connected or severed from one another, before the portions are finally severed to obtain dice or chips.

At S145, according to some implementations, the wafer substrate 200 is subjected to grinding as shown in FIG. 2H. It should be understood that, while steps of the process described above are performed on the front side or top face of the wafer, grinding or otherwise thinning of the wafer substrate is performed on the back side or bottom face of the wafer. At least one effect can be that the wafer substrate is thinned. In some implementations, grinding is performed until the buried first etch stop layer 210 is reached. In some implementations, grinding is stopped prior, in one embodiment in particular just prior, to reaching the buried first etch stop layer 210.

At S150, as shown in FIG. 2I, the wafer substrate 200 is subjected to etching. At least one effect can be that the thickness of the wafer is further reduced beyond removal of the wafer substrate 200 during wafer thinning by grinding. In some embodiments the etchant is selected from a group consisting of quaternary ammonium salt such as tetramethylammonium hydroxide (TMAH), potassium hydroxide (KOH), and other alkaline solution.

Outside the dicing areas 202, the etchant can be stopped by the first etch stop layer 210. Thus, the thickness of the device layer 220 essentially determines the thickness of the thinned wafer. In some embodiments, the thickness of the device layer 220 is equal to or less than 180 micrometer. In some embodiments, the thickness of the device layer 220 exceeds, for example, 10 micrometer or even 50 micrometer or even 100 micrometer or even 150 micrometer. In some embodiments, the thickness of the device layer 220 is only 10 micrometer. Where, as described above, the device layer 220 is adapted to provide a predetermined blocking voltage, this voltage applies between the top metal layer 240 and the bottom face of the thinned wafer or a field stop layer (not shown), respectively.

Inside the dicing areas 202, etching the wafer substrate is performed beyond a plane with the first etch stop layer 210. In some implementations, the etching is performed anisotropically. An exemplary etchant solution, for example, comprises tetramethylammonium hydroxide (TMAH) or potassium hydroxide (KOH). At least one effect can be that substrate material in the device layer 220 is provided with sloped side walls 221, 222 in the dicing areas 202. In other words, the side walls 221, 222 are inclined or tilted with respect to the support plane of the semiconductor device. However, as earlier in the process the dicing portions 202 of the wafer substrate 200 were left uncovered from the first etch stop material, the etchant can work itself into the semiconductor material of the device layer 220 until the etchant reaches the second etch stop layer 230 where the etchant is kept from etching further towards the top face of the wafer. Thus, the device layer 220 can be removed from the dicing areas 202 while the active areas 201, and consequently the semiconductor devices, are protected by the first etch stop layer 210. At least one effect can be that etchant can form trenches 215 between areas that are covered by etch stop material deposited to form the first etch stop layer 210. Thus, the material of the second etch stop layer 230 can provide a floor of trenches 215 formed in the dicing areas. At least one effect can be to reduce a risk that side walls of the semiconductor device get contaminated with particles from the imide of the adhesive carrier 260 and/or reactants from the substrate material etch process.

In some implementations (not shown), the first etch stop layer is then removed by etching using, for example, a hydrofluoric acid (HF).

Some implementations (not shown) further comprise, after performing the etching of the wafer substrate, doping side walls of the substrate layer in the dicing area with protons. At least one effect can be that the side walls can provide lateral channel stoppers and/or a field stops. Some implementations (not shown) comprise, after performing the etching of the wafer substrate, doping side walls of the substrate layer in the dicing area with donors such as a group V material, for example, phosphorus (P) and/or arsenic (As) and/or antinomy (Sb). At least one effect can be that the side walls of the substrate layer can be provided with lateral channel stoppers. In some implementations, proton irradiation can be combined with a field stop generation. In some implementations, a separation diffusion is provided by doping the side walls with acceptors such as a group III material, for example, boron (B) and/or aluminum (Al). The separation diffusion can be a deep diffusion performed via the front face of the wafer resulting in pn-junctions which penetrate at least part of the wafer body. At least one effect can be an electrical separation of different chip areas adjacent to the pn-junctions. In some implementations, a backside terminal of the semiconductor device is formed by doping. For example, a p-doped backside emitter of a power transistor as the semiconductor device can thus be provided. In some implementations, the afore-described steps of providing side wall protection and/or backside terminal are combined. In some implementations, an n-doped backside drain layer will be formed.

Some implementations further comprise depositing metal on the wafer substrate. At least one effect can be that the wafer substrate can be provided with a supportive back side metallization layer that, in the dicing areas, follows the contour of the sloped side wall to protect the side wall. In some embodiments, the side walls 221, 222 are completely covered by metal. At least one effect can be that protection of the semiconductor device layer 220 from adverse effects of thermal and/or mechanical stress is particularly enhanced.

In some implementations, at S155, the wafer backside is first provided with a protection layer 270. For example, a barrier layer material is deposited on the wafer as illustrated in FIG. 2J. In some embodiments the barrier layer material is selected from a group consisting of titanium-tungsten, titanium nitride, tantalum nitride (TaN), titanium (Ti), tantalum (Ta), and any combination or stack thereof. At least one effect can be that the active area can be protected against electro-migration from a metal layer to be formed on the protection layer 270.

At S160, a metal support layer 280 is deposited on a bottom face of the wafer, in particular, in some embodiments, on the protection layer 270 as illustrated in FIG. 2K. In some embodiments, electrochemical deposition is used to deposit the metal. The metal support layer 280 can have, for example, a thickness of from 5 to 50 micrometer. In some embodiments, the thickness of the metal support layer 280 is from 10 to 20 micrometer. At least one effect can be that the metal support layer 280 provides a heat sink. One effect can be that the die is mechanically stabilized.

In some embodiments, the metal comprises copper. In some embodiments the metal support layer 280 is provided as a copper layer. In some implementations, forming the metal support layer 280 comprises depositing a seed layer (not shown) for the metallization. For example, a sputtering technique can be used to form the seed layer. At least one effect can be that metal can better be deposited on the seed layer material so as to form a back side metallization of the dice to be. In some embodiments the seed layer material is selected from a group consisting of zinc oxide (ZnO), copper (Cu), and silver (Ag).

At S165, the metal support layer 280 can be structured is illustrated in FIG. 2L. For example, a dicing trench or dicing channel 290 can be formed by removing metal from the dicing areas 202. Some implementations use etching such as wet etching. In some implementations plasma etching can be performed. The etching step can be stopped at the second etch stop layer 230. At least one effect can be to reduce a risk that side walls of the semiconductor device get contaminated with particles from the adhesive carrier 260 and/or reactants from the etch process that would otherwise result from contact of etchant with the adhesive. The second etch stop layer 230 thus forms bridges between the active portions and, thus, mechanically connects adjacent active portions to one another.

In some implementations, an inkjet printing step can be performed to fill dicing channels 290 with a protective material such as an imide or an epoxy (not shown). Thus, protected, a dicing step can be performed, for example, a sawing step, in order to separate dice from the wafer. In some implementations, a laser is used to perform the dicing (not shown).

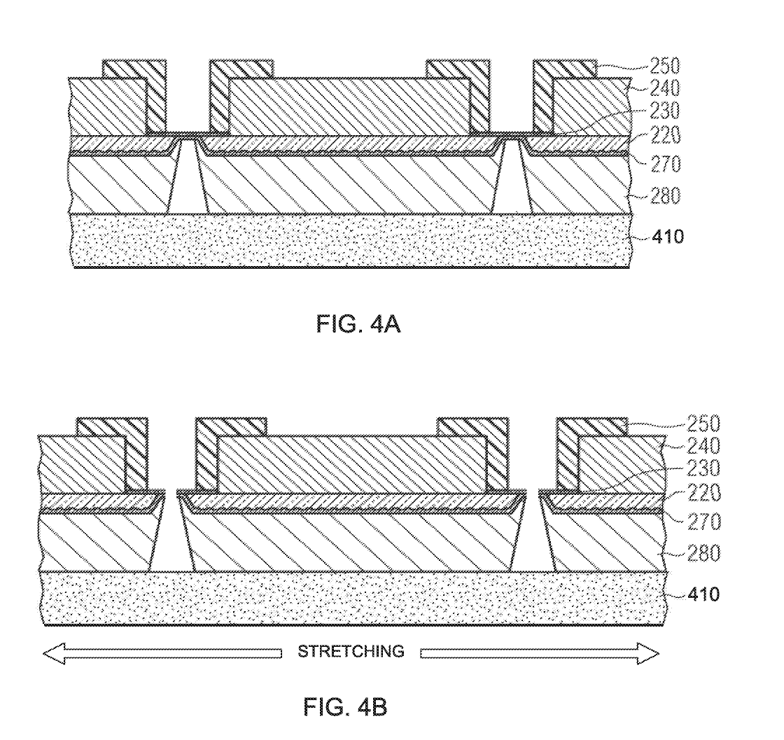

In some implementations, where the adhesive carrier is an adhesive support tape, at S110, the adhesive carrier 260 holding the wafer substrate is expanded as indicated in FIG. 2M. For example, the support tape is stretched. In an alternate implementation, as indicated in FIG. 4A, the wafer is set, bottom face down, onto a framed support foil 410. The adhesive carrier can be removed while the wafer sticks to the framed support foil 410. Then, as indicated in FIG. 4B, the framed support foil 410 can be stretched by frame expansion. At least one effect of the stretching can be that the bridges between portions of the wafer break. Thus, active portions 201 formed on the wafer are finally separated from one another to become separate semiconductor dice.

At S175, the support carrier is removed to singulate the separate semiconductor dice.

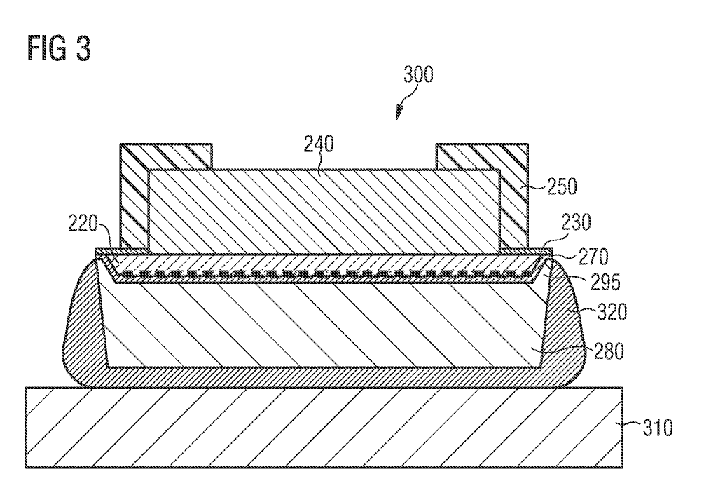

At S180, the singulated dice can be soldered to lead frames as, for example, in an embodiment illustrated in FIG. 3.

Generally, the disclosure encompasses a semiconductor device chip. The semiconductor device chip comprises a device layer comprising a semiconductor device. The semiconductor device chip further comprises a metal support layer supporting the device layer. In some embodiments the metal support layer forms a metal side wall protection of the substrate material layer. In some embodiments a side wall of the device layer is inclined with respect to a side wall of the semiconductor device chip. In particular, the side wall of the device layer can be inclined with respect so a substantially vertical side wall of the semiconductor device chip. In some embodiments, a plane that includes a portion of the side wall of the device layer is non-perpendicular to a plane that includes an essentially planar bottom surface of the metal support layer. In some embodiments a substrate material of the device layer is selected from a group consisting of silicon, silicon carbide, gallium arsenide and gallium nitride. In some embodiments the device comprises a micro-electro-mechanical system (MEMS).

Some embodiments of the semiconductor device chip comprise a lead frame soldered to the metal layer, wherein the substrate material of the device layer is essentially not exposed to solder or not at all exposed to solder.

Some embodiments of the semiconductor device chip comprise at least one bridgehead portion that extends laterally from the semiconductor device chip. The bridgehead portion can be form from expanding a carrier tape that supports a wafer having a plurality of dies connected to one another by bridges. In some embodiments a footprint of the semiconductor device chip has a non-rectangular shape.

FIG. 3 illustrates a cross-sectional side view of a semiconductor die that was manufactured using the steps of the exemplary method described above and soldered onto a lead frame.

In some embodiments, as shown in FIG. 3, the side wall profile of the device layer 220 is inclined rather than vertical to the support plane of the semiconductor device as defined originally by the top surface of the wafer 200. The inclination of the side wall can depend on the etchant that, in step S150, not only works its way through the device layer 220 of substrate material to the second etch stop layer 230 but also works on the side wall of the substrate material formed in the device layer 220. Albeit, where the etching is anisotropic, the removal of substrate material from the sidewall can be performed at a rate and/or to an extent that is less than with the removal of substrate material from the floor of the etched trench.

In some embodiments, as shown in FIG. 3, the protection layer 270 covers the sidewall of the die. The metal of the protection layer 270 conducts heat better than the substrate material of the device layer 220. During soldering the die 300 to the lead frame 310, the thermal conductivity of the metal can thus reduce heat stress on the substrate material of the die. Cracks are thus less likely to occur when compared to soldering a die whose sidewall does not have the metal cover of the embodiments disclosed herein.

It should be understood that some of the methods disclosed herein can be used to form dice that have an arbitrary foot-print. In particular, as chips can be manufactured with rounded edges, chips can be circular.

As described above, a blocking pn-junction can be formed by at least two regions that differ from one another in terms of density of dopants (lower doped region and higher doped region). In some implementations, a wet etch angle can be used to provide a termination of the pn-junction. In some embodiments, the blocking pn-junction can be terminated using a positive inclination angle of the sidewall with respect to the support plane of the semiconductor device. In this case, more material is removed along the lower doped region compared to the higher doped region while both regions form the blocking pn-junction. At least one effect can be that the positive angle enables a good blocking behaviour and/or is a robust against surface charges. One effect can also be less area consumption when compared to typical planar junction terminations such as field rings, field plates etc.

The implementations are described herein in terms of exemplary embodiments. However, it should be appreciated that individual aspects of the implementations may be separately claimed and one or more of the features of the various embodiments may be combined. In some instances, well-known features are omitted or simplified to clarify the description of the exemplary implementations.

It should be noted that views of exemplary embodiments are merely to illustrate selected features of the embodiment. In particular, cross-sectional views are not drawn to scale and dimensional relationships of the illustrated structures can differ from those of the illustrations. For example, while in the drawings the top metal layer 240 is shown as being thicker than the device layer 220, in other embodiments the top metal layer could be thinner than the device layer. For example, the device layer could have a thickness of 100 micrometer while the top metal layer could have a thickness of 2 micrometer.

In the above description of exemplary implementations, for purposes of explanation, specific numbers, materials configurations, and other details are set forth in order to better explain the invention, as claimed. However, it will be apparent to one skilled in the art that the claimed invention may be practised using different details than the exemplary ones described herein. It is further to be understood that the features of the various embodiments described herein may be combined with each other, unless specifically noted otherwise.

Some or all method steps described herein may be executed by (or using) a hardware apparatus, like for example, a microprocessor, a programmable computer or an electronic circuit. Other embodiments include the computer program for performing one of the methods described herein, stored on a machine readable carrier.

Although specific embodiments have been illustrated and described herein, it will be appreciated by those of ordinary skill in the art that a variety of alternate and/or equivalent implementations may be substituted for the specific embodiments shown and described without departing from the scope of the present invention. For example, in order to provide the first etch stop material in a buried layer of the wafer, an ion beam implantation process such as a separation-by-implantation-of-oxygen (SIMOX) process can be performed on the wafer substrate using oxygen ions or other ions such carbon ions, nitrogen ions as implants. In still another implementation, an electro-chemical process can be performed, for example, to implant boron in the wafer substrate in order to form the first edge stop layer. Annealing of the wafer can thus create the buried first etch stop layer. In another implementation, the first etch-stop layer may also be created by an implantation of n-type dopant on a p-type doped substrate. In this case, etching using an alkaline etchant can be terminated at the pn-junction by applying an anodic voltage to the n-doped region. This application is intended to cover any adaptations or variations of the specific embodiments discussed herein. It is intended that this invention be limited only by the claims and the equivalents thereof.

As used herein, the word ‘exemplary’ means serving as an example, instance, or illustration. Any aspect or design described herein as ‘exemplary’ is not necessarily to be construed as preferred or advantageous over other aspects or designs. Rather, use of the word exemplary is intended to present concepts and techniques in a concrete fashion. The term ‘techniques,’ for instance, may refer to one or more devices, apparatuses, systems, methods, articles of manufacture, and/or computer-readable instructions as indicated by the context described herein.

As used herein, the term ‘or’ is intended to mean an inclusive ‘or’ rather than an exclusive ‘or.’ That is, unless specified otherwise or clear from context, ‘X employs A or B’ is intended to mean any of the natural inclusive permutations. That is, if X employs A; X employs B; or X employs both A and B, then ‘X employs A or B’ is satisfied under any of the foregoing instances.

As used herein, the articles ‘a’ and ‘an’ should generally be construed to mean ‘one or more,’ unless specified otherwise or clear from context to be directed to a singular form.

As used herein, the terms ‘having’, ‘containing’, ‘including’, ‘with’ or variants thereof, and like terms are open ended terms intended to be inclusive. These terms indicate the presence of stated elements or features, but do not preclude additional elements or features.

As used herein, directional terminology, such as ‘top’, ‘bottom’, ‘front’, ‘back’, ‘leading’, ‘trailing’, etc., is used with reference to the orientation of the figure(s) being described.

As used herein, terms such as ‘first’, ‘second’, and the like, are also used to describe various elements, regions, sections, etc. and are also not intended to be limiting.

What is claimed is:

1. A method of fabricating a semiconductor device, the method comprising:
providing a wafer substrate that comprises dicing areas;
providing a first etch stop material outside the dicing areas; and
inside the dicing areas, etching the wafer substrate down beyond a plane with the first etch stop material.

2. The method of claim 1, further comprising
depositing a second etch stop material inside the dicing areas.

3. The method of claim 2, further comprising
after providing the first etch stop material layer and before depositing the second etch stop material layer, depositing a substrate material to form a device layer.

4. The method of claim 1, wherein the etching is performed anisotropically.

5. The method of claim 1, further comprising
depositing a seed layer material for metallization on the wafer substrate.

6. The method of claim 1, further comprising
after depositing the second etch stop layer, removing the first etch stop layer.

7. The method of claim 1, further comprising
after performing the etching of the wafer substrate, doping side walls of the substrate layer in the dicing area with protons.

8. The method of claim 1, further comprising
after performing the etching of the wafer substrate, doping side walls of the device layer in the dicing area with at least one of boron, aluminium, phosphorus, arsenic or antimony.

9. The method of claim 5, further comprising
depositing metal on the seed layer.

10. The method of claim 1, further comprising
prior to separating portions of the wafer substrate from one another, mounting the wafer substrate on a support foil.

11. The method of claim 1, further comprising expanding the support foil holding the wafer substrate.

12. A semiconductor device chip, the semiconductor device chip comprising
a device layer comprising a semiconductor device; and
a metal support layer supporting the device layer,
wherein the metal support layer provides a metal side wall protection of the device layer.

13. The semiconductor device chip of claim 12, wherein a side wall of the device layer is inclined with respect to a side wall of the semiconductor device chip.

14. The semiconductor device chip of claim 12, wherein a footprint of the semiconductor device chip has a non-rectangular shape.

15. The semiconductor device chip of claim 12, further comprising at least one bridgehead portion that extends laterally from the semiconductor device chip.

16. The semiconductor device chip of claim 12, wherein a substrate material of the device layer is selected from a group consisting of silicon, silicon carbide, gallium arsenide and gallium nitride.

17. The semiconductor device chip of claim 12, wherein a thickness of the device layer is selected to provide a blocking capability above a predetermined breakdown voltage.

18. The semiconductor device chip of claim 12, wherein the thickness of the device layer is equal to or less than 180 μm.

19. The semiconductor device chip of claim 12, wherein the device comprises a micro-electro-mechanical system (MEMS).

20. The semiconductor device chip of claim 12, further comprising a lead frame soldered to the metal support layer, wherein the device layer is not exposed to solder.
